(19) United States
(12) Patent Application Publication
(10) Pub. No.: US 2009/0056804 A1
(43) Pub. Date: Mar. 5, 2009

(54) SOLAR CELL

(75) Inventor: Yuji HISHIDA, Osaka City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/198,254

(22) Filed: Aug. 26, 2008

(30) Foreign Application Priority Data
Sep. 4, 2007 (JP) JP2007-229448

(51) Int. Cl. H01L 31/00

(52) U.S. Cl. 136/256

(57) ABSTRACT

A solar cell having a through-hole electrode with an improved manufacturing yield is provided. The solar cell includes a through-hole passing through a photoelectric converter from a light-receiving surface to the back surface of the photoelectric converter. One end portion on the back surface side of the through-hole branches off in multiple back surface side branch portions and the back surface side branch portions open on the back surface of the photoelectric converter.

### CROSS REFERENCE TO RELATED APPLICATIONS

This application claims priority based on 35 USC 119 from prior Japanese Patent Application No. P2007-229448 filed on Sep. 4, 2007, the entire contents of which are incorporated herein by reference.

### BACKGROUND OF THE INVENTION

1. Field of the Invention

The present invention relates to solar cells that include a through-hole electrode.

2. Description of Related Art

Solar cells directly convert sun-light, which is clean and of unlimitedly supply, into electricity. Accordingly, solar cells are anticipated to be a new energy source.

Output of a single solar cell is approximately a several watts. Accordingly, when solar cells are used as power sources for houses, buildings, and the like, solar cell modules in which multiple solar cells are connected by wiring materials are used.

In general, a solar cell includes a photoelectric converter configured to generate photo-generated carriers when receiving light and a collecting electrode configured to collect the photo-generated carriers from the photoelectric converter. The collecting electrode is formed on a light-receiving surface side and a back surface side of the photoelectric converter. A wiring material is connected to the light-receiving surface side collecting electrode of one solar cell and the back surface side collecting electrode of another solar cell adjacent to the solar cell.

Here, K. M. Broek disclosed the following solar cell in “Testing Interconnections using Conductive Adhesives for Application in PV modules” presented in the 21^{st} European Photovoltaic Solar Energy Conference held in Dresden in 2006. The solar cell includes through-hole electrodes formed by filling a conductive material into through-holes passing through the photoelectric converter from the light-receiving surface to the back surface. The through-hole electrodes are electrically connected to the light-receiving surface side collecting electrodes on the light-receiving surface of the photoelectric converter. Thereby, wiring materials can be provided on the back surface of the photoelectric converter. As a result, an area of the light-receiving surface of the solar cell can be increased.

Here, the through-holes are formed by using a laser device or the like. Accordingly, the inside of the photoelectric converter is easily damaged in the process of forming the through-holes. Thus, it is preferable that the number of through-holes be small. For this reason, it is possible that a diameter of each through-hole is increased. Thereby, a larger current is allowed to flow while resistance of a through-hole electrode can be maintained low. Thus, the number of through-holes can be reduced.

However, if a conductive material with low viscosity, which can fill a through-hole, is filled into a through-hole with a large diameter, the conductive material tends to flow out easily under its own weight. As a result, the manufacturing yield of solar cells suffers.

### SUMMARY OF THE INVENTION

An aspect of the invention provides a solar cell that comprises: a photoelectric converter having a first surface and a second surface provided on the opposite side to the first surface configured to generate photo-generated carriers when receiving light; a through-hole passing through the photoelectric converter from the first surface to the second surface; and a through-hole electrode having a conductive material filled into the through-hole, wherein one end portion on the first surface side of the through-hole branches off in multiple first surface side branch portions and the first surface side branch portions are open on the first surface.

As described above, the through-hole has multiple first main surface side branch portions, each of which has a small opening area. Accordingly, even when a conductive material having fluidity is filled into the first main surface side branch portions, the conductive material can be prevented from flowing out from the openings of the first main surface side branch portions. Thereby, a solar cell having a through-hole electrode with improved manufacturing yield can be archived.

### BRIEF DESCRIPTION OF THE DRAWINGS

FIG. 1 is a plan view showing a light-receiving surface side of solar cell 1 according to a first embodiment.

FIG. 2 is a plan view showing a back surface side of solar cell 1 according to the first embodiment.

FIG. 3 is a partially-enlarged view of FIG. 2.

FIG. 4 is an enlarged cross-sectional view taken along the A-A line in FIG. 1.

FIG. 5 is an enlarged cross-sectional view taken along the B-B line in FIG. 1.

FIG. 6 illustrates a method for manufacturing solar cell 1 according to the first embodiment.

FIG. 7 illustrates a method for manufacturing solar cell 1 according to the first embodiment;

FIG. 8 is a plan view showing a light-receiving surface side of solar cell 2 according to a second embodiment.

FIG. 9 is a plan view showing a back surface side of solar cell 2 according to the second embodiment.

FIG. 10 is a cross-sectional view taken along the C-C line in FIG. 8.

FIG. 11 is a cross-sectional view taken along the D-D line in FIG. 8.

### DETAILED DESCRIPTION OF EMBODIMENTS

Descriptions are provided hereinbelow for embodiments based on the drawings. All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

### Schematic Configuration of a Solar Cell

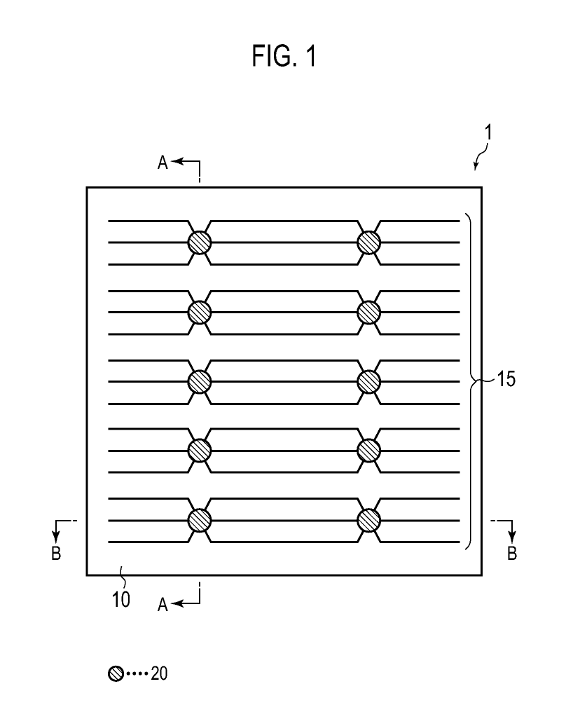

The schematic configuration of a solar cell according to a first embodiment is described by referring to FIGS. 1 to 3.

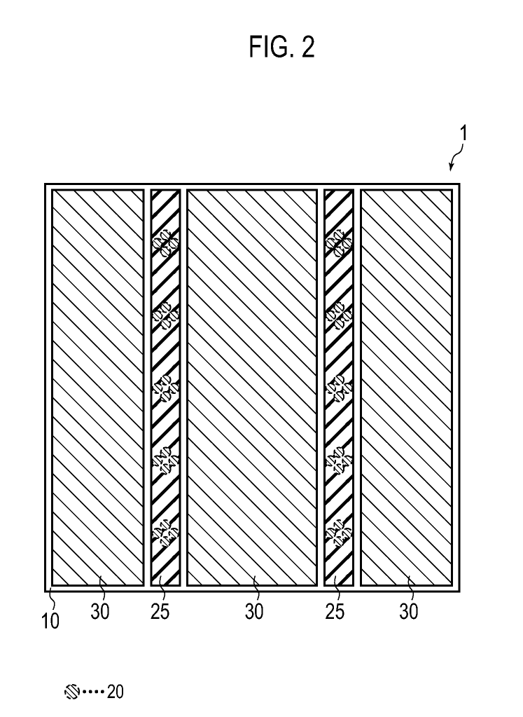

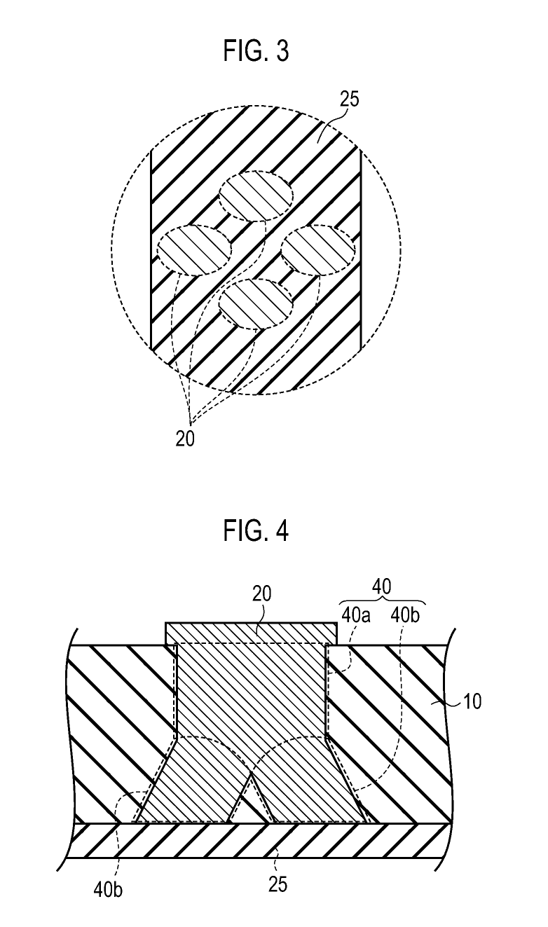

FIG. 1 is a plan view showing a light-receiving surface side of solar cell 1 according to the embodiment. FIG. 2 is a plan view showing aback surface side of solar cell 1 according to the embodiment. FIG. 3 is a partially-enlarged view of FIG. 2.

Solar cell 1 includes: photoelectric converter 10; light-receiving surface side collecting electrodes 15; through-hole electrodes 20; light-receiving surface side bus bar electrodes 25; and back surface side collecting electrodes 30.

Photoelectric converter 10 has a light-receiving surface on which light falls and a back surface provided on the opposite side to the light-receiving surface. Photoelectric converter 10 generates photo-generated carriers when light falls on the light-receiving surface. The “photo-generated carriers” mean holes and electrons generated when photoelectric converter 10 absorbs sun-light.

Photoelectric converter 10 has a semiconductor junction, such as a semiconductor p-n junction or a semiconductor p-i-n junction, as the basic structure. Photoelectric converter 10 can be formed of a crystalline semiconductor material, such as single crystal Si or polycrystalline Si, or another semiconductor material, such as a compound semiconductor material, for example, GaAs or InP. Note that photoelectric converter 10 may have a structure in which a substantially intrinsic amorphous silicon layer is inserted between a single crystal silicon substrate and an amorphous silicon layer, that is, the HIT structure.

Light-receiving surface side collecting electrodes 15 are configured to collect photo-generated carriers generated in photoelectric converter 10. As shown in FIG. 1, multiple light-receiving surface side collecting electrodes 15 are formed across a substantially entire region of the light-receiving surface of photoelectric converter 10. Light-receiving surface side collecting electrode 15 can be formed by, for example, print processes using a thermosetting conductive paste. The number and shapes of light-receiving surface side collecting electrodes 15 are properly set by considering the size of photoelectric converter 10 and the like.

Through-hole electrode 20 passes through photoelectric converter 10 from the light-receiving surface to the back side of photoelectric converter 10. Through-hole electrode 20 is formed within through-hole 40 (see, FIG. 4) passing through photoelectric converter 10 from the light-receiving surface to the back surface of photoelectric converter 10. Through-hole electrode 20 is formed by filling with through-hole 40 a conductive material. A similar material to that of light-receiving surface side collecting electrode 15 can be used as the conductive material.

Here, one end portion on the back surface side of through-hole electrode 20 according to the embodiment branches off in four. Accordingly, as shown in FIG. 3, through-hole electrode 20 has four separated end surfaces.

In addition, as shown in FIG. 1, through-hole electrode 20 is electrically connected to multiple light-receiving surface side collecting electrodes 15 on the light-receiving surface side of photoelectric converter 10. Accordingly, the photo-generated carriers collected from photoelectric converter 10 by multiple light-receiving surface side collecting electrodes 15 are collected in one through-hole electrode 20 and then conveyed to the back surface side of photoelectric converter 10. In the embodiment, two-paralleled rows of five through-hole electrodes 20 are formed. However, the areas of the end surfaces of through-hole electrodes 20 and the number of through-hole electrodes 20 can be properly set by considering the number of light-receiving surface side collecting electrodes 15 connected to one through-hole electrode 20 and resistivity of the conductive material to be used.

Light-receiving surface side bus bar electrodes 25 are configured to collect photo-generated carriers from through-hole electrodes 20 on the back surface of photoelectric converter 10. As shown in FIG. 2, light-receiving surface side bus bar electrodes 25 are formed in a line form in a predetermined direction. Here, the predetermined direction means a direction in which the row of five through-hole electrodes 20 extends on the light-receiving surface side of photoelectric converter 10. Light-receiving surface side bus bar electrodes 25 can be formed from a material similar to that used for light-receiving surface side collecting electrodes 15.

Back surface side collecting electrodes 30 collect, from photoelectric converter 10, photo-generated carriers having opposite polarity to the photo-generated carriers collected by light-receiving surface side bus bar electrodes 25. Back surface side collecting electrodes 30 are formed in a substantially entire region on the back surface of photoelectric converter 10, except the region where light-receiving surface side bus bar electrodes 25 are formed. However, the collecting electrodes formed on the back surface of photoelectric converter 10 can be in any shape and not limited to the above-described shape.

Here, back surface side collecting electrodes 30 collect photo-generated carriers having the opposite polarity to those collected by through-hole electrodes 20 and light-receiving surface side bus bar electrodes 25. Accordingly, as shown in FIG. 2, back surface side collecting electrodes 30 are electrically seperated from through-hole electrodes 20 and light-receiving surface side bus bar electrodes 25. In addition, each through-hole electrode 20 is electrically insulated from photoelectric converter 10 forming an inner wall of through-hole 40 by an unillustrated insulating film. Furthermore, light-receiving surface side bus bar electrodes 25 are electrically insulated from the back surface of photoelectric converter 10 by an unillustrated insulating film.

In order to electrically connect multiple solar cells 1 to each other, light-receiving surface side bus bar electrodes 25 of one solar cell 1 and back surface side collecting electrodes 30 of adjacent another solar cell 1 are connected by wiring materials. Accordingly, wiring materials are only provided on the back surface side of solar cell 1.

### Configurations of Through-Hole Electrode and Through-Hole

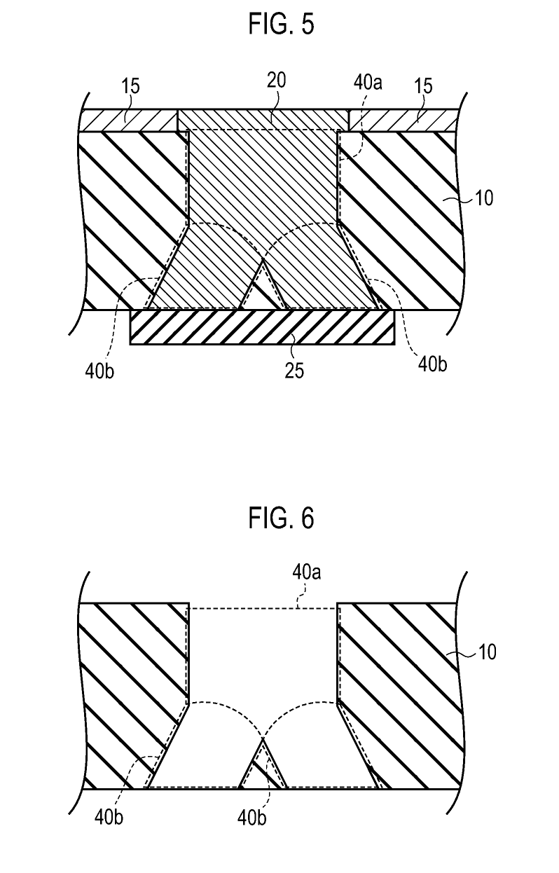

Next, the configurations of through-hole electrode 20 and through-hole 40 are described by referring to FIGS. 4 and 5. FIG. 4 is an enlarged cross-sectional view taken along the A-A line in FIG. 1. FIG. 5 is an enlarged cross-sectional view taken along the B-B line in FIG. 1.

As shown in FIGS. 4 and 5, through-hole 40 passing through photoelectric converter 10 includes one light-receiving surface side trunk portion 40a and four back surface side branch portions 40b.

Light-receiving surface side trunk portion 40a extends from the light-receiving surface of photoelectric converter 10 to the inside thereof in a direction substantially perpendicular to the main surface of solar cell 1 (hereinafter referred to as “first direction”). Four back surface side branch portions 40b are continuous to light-receiving surface side trunk portion 40a in the inside of photoelectric converter 10. Back surface side branch portions 40b radially extend from a position continuous to light-receiving surface side trunk portion 40a to the back surface of photoelectric converter 10. Accordingly, a direction in which back surface side branch portion 40b extends (hereinafter referred to as “second direction”) is inclined to the first direction.

As described above, one end portion of through-hole 40 on the back surface side of photoelectric converter 10 branches off in multiple back surface side branch portions 40b. Each back surface side branch portion 40b opens on the back surface of photoelectric converter 10. In addition, light-receiving surface side trunk portion 40a opens on the light-receiving surface side of photoelectric converter 10.

Through-hole electrode 20 is formed by filling a conductive material into through-hole 40. Accordingly, in the embodiment, through-hole electrode 20 branches off in four in the inside of photoelectric converter 10.

Here, it is preferable that an electrical resistance in an interface between light-receiving surface side collecting electrode 15 and through-hole electrode 20 be equal to that between light-receiving surface side bus bar electrode 25 and through-hole electrode 20. Accordingly, it is preferable that an opening area on the light-receiving surface of light-receiving surface side trunk portion 40a be equal to the total of opening areas on the back surfaces of four back surface side branch portions 40b.

Here, a diameter of light-receiving surface side trunk portion 40a preferably may be at least 0.01 μm in terms of grain size of conductive particle in conductive material, and more preferably at least 10 μm in terms of grain size of conductive particle in low cost conductive material. In addition, a diameter of back surface side branch portion 40b preferably may be at least 0.01 μm and no more than 2 mm in terms of grain size and viscosity of conductive material, and more preferably at least 10 μm and no more than 2 mm in terms of grain size and viscosity of low cost conductive material. In the embodiment, the diameter of light-receiving surface side trunk portion 40a is set to 0.5 mm and the diameter of back surface side branch portion 40b is set to 0.25 mm.

In addition, preferably the inner resistance values of through-hole electrodes 20 are uniform. Accordingly, it is preferable that a cross-sectional area of light-receiving surface side trunk portion 40a in the cross-section perpendicular to the first direction be equal to the total of cross-sectional areas of respective back surface side branch portions 40b in the cross-section vertical to the second direction.

In FIG. 5, through-hole electrode 20 and light-receiving surface side collecting electrode 15 are separated. However, they may be integrally formed in one process.

Although unillustrated, preferably, through-hole electrode 20 and photoelectric converter 10 are electrically insulated by applying an insulating process or by forming an insulating film on the inner wall of through-hole 40.

### Method for Manufacturing the Solar Cell

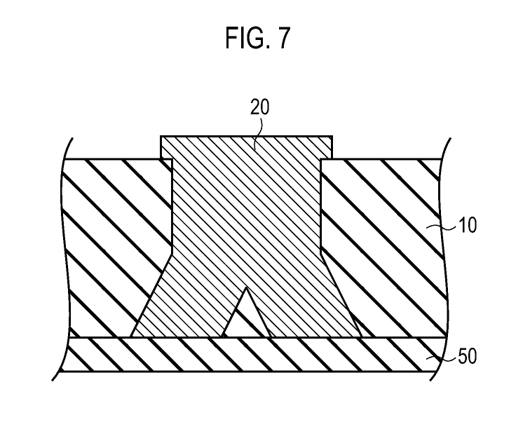

Next, a method for manufacturing solar cell 1 is described by referring to FIGS. 6 and 7.

First, through-hole 40 is formed in photoelectric converter 10. Through-hole 40 can be formed by a laser method, etching method, sandblast method, or the like. For example, when the laser method is used, light-receiving surface side trunk portion 40a is first formed by laser irradiation from the light-receiving surface side of photoelectric converter 10. Subsequently, four back surface side branch portions 40b are formed by sequentially changing a laser irradiation angle. Thereby, through-hole 40 shown in FIG. 6 is formed.

The method for forming through-hole 40 is not limited to this. Through-hole 40 may be formed by sequentially forming back surface side branch portion 40b and light-receiving surface side trunk portion 40a by laser irradiation from the back surface side of photoelectric converter 10. In addition, light-receiving surface side trunk portion 40a may be formed by laser irradiation form the light-receiving surface side of photoelectric converter 10 and back surface side branch portion 40b may be formed by laser irradiation from the back surface side.

Next, as shown in FIG. 7, photoelectric converter 10 is mounted on stage 50 with the back surface of photoelectric converter 10 facing down. That is, photoelectric converter 10 is mounted with the openings of back surface side branch portions 40b facing down. Subsequently, an insulating film is formed in an inner wall of through-hole 40 by a well-known method.

Then, a conductive material fills through-hole 40 by a printing method, such as a screen printing method, off-set printing method, or ink-jet method. Thereby, through-hole electrode 20 is formed. As the conductive material, a silver paste in which silver particles are kneaded with an epoxy-based thermosetting resin or the like may be used. It is preferable that such conductive material have fluidity (low viscosity) so as to be closely filled into through-hole 40.

Next, a conductive material with a predetermined pattern is provided on the light-receiving surface and back surface of photoelectric converter 10. Here, the predetermined pattern means shapes of light-receiving surface side collecting electrodes 15, light-receiving surface side bus bar electrodes 25, and back surface side collecting electrodes 30, as shown in FIGS. 1 and 2. As the conductive material, as in the case of through-hole electrode 20, a silver paste in which silver particles are kneaded with an epoxy-based thermosetting resin or the like may be used. Thus, the present process may be carried out together with the process of filling the conductive material into through-hole 40.

Note that insulating films should be formed in advance in portions, where light-receiving surface side bus bar electrodes 25 are formed, of the back surface of photoelectric converter 10.

### Advantageous Effects

Solar cell 1 according to an embodiment includes through-hole 40 passing through photoelectric converter 10 from the light-receiving surface to back surface of photoelectric converter 10. One end portion on the back surface side of through-hole 40 branches off in multiple back surface side branch portions 40b and back surface side branch portions 40b open on the back surface of photoelectric converter 10.

As described above, through-hole 40 has multiple back surface side branch portions 40b, each having a small opening area. Accordingly, even when a conductive material having fluidity is filled into the back surface side branch portions 40b, the conductive material can be prevented from flowing out from the openings on the back surface side of back surface side branch portions 40b.

Specifically, the conductive material is poured from the opening of light-receiving surface side trunk portion 40a. The opening area of back surface side branch portion 40b is small, and thus the conductive material hardly flows out from the openings of back surface side branch portions 40b even if photoelectric converter 10 is lifted. As a result, the conductive material can be closely filled into through-hole 40. Thus, manufacturing yield of solar cell 1 can be improved.

As described above, even if an end surface area of through-hole 40 is increased, the conductive material hardly flows out because the opening area of one back surface side branch portion 40b is small. Since a large current is allowed to flow in such through-holes 40, the number of through-holes 40 can be reduced.

Accordingly, in the process of forming through-hole 40, the possibility of damage to the inside of photoelectric converter 10 can be reduced. In addition, the total area of the inner walls of through-holes 40 can be reduced by increasing the diameter of through-hole 40. Accordingly, in the process of forming through-hole 40, the damaged area inside of photoelectric converter 10 can be reduced.

In addition, a conductive material having higher fluidity can be used so that flexibility in selecting a conductive material can be improved. As a result, light-receiving surface side collecting electrode 15, light-receiving surface side bus bar electrode 25, and back surface side collecting electrode 30 can be formed of the same composition material as that of through-hole electrode 20. Accordingly, these can be formed in one process, so that manufacturing processes can be simplified and manufacturing cost can be reduced.

### Second Embodiment

A second embodiment is described by referring to drawings. The embodiment is different from the first embodiment in that through-hole 40 has light-receiving surface side branch portions 40c.

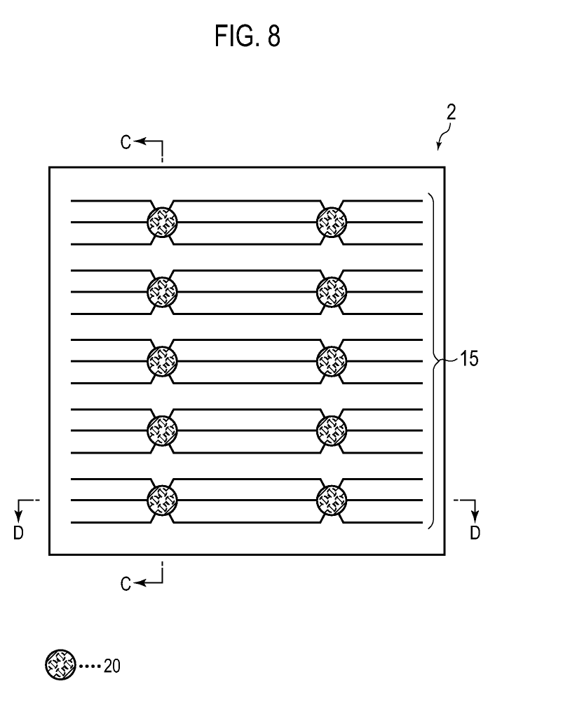

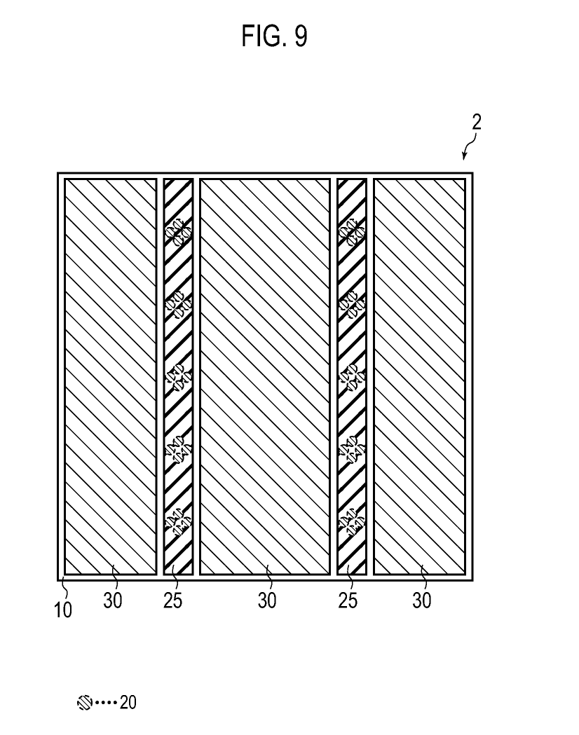

FIG. 8 is a plan view showing a light-receiving surface side of solar cell 2 according to the embodiment. FIG. 9 is a plan view showing aback surface side of solar cell 2 according to the embodiment. As shown in FIGS. 8 and 9, the schematic configuration of a solar cell is similar to that of the first embodiment, and the description thereof will not be repeated.

### Configurations of Through-Hole and Through-Hole Electrode

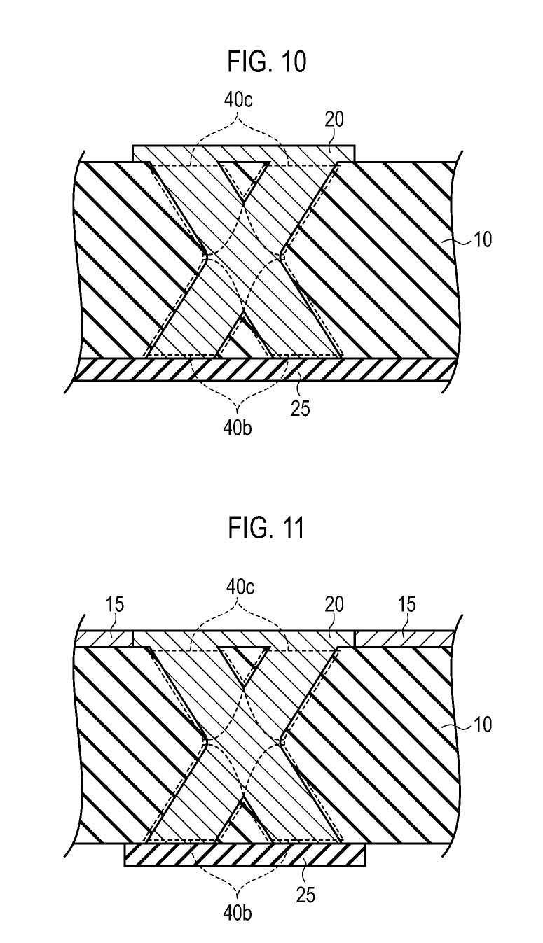

Next, the configurations of through-hole 40 and through-hole electrode 20 of the embodiment are described by referring to FIGS. 10 and 11. FIG. 10 is an enlarged cross-sectional view taken along the C-C line in FIG. 8. FIG. 11 is an enlarged cross-sectional view taken along the D-D line in FIG. 8.

As shown in FIGS. 10 and 11, through-hole 40 passing through photoelectric converter 10 includes four light-receiving surface side branch portions 40c and four back surface side branch portions 40b. Four light-receiving surface side branch portions 40c extend from the light-receiving surface to an inside of photoelectric converter 10 in a predetermined direction. Four back surface side branch portions 40b are continuous to light-receiving surface side branch portions 40c inside of photoelectric converter 10. Accordingly, through-hole 40 of the embodiment is formed so that four through-holes, each having a small diameter, would intersect with each other. One pair of light-receiving surface side branch portion 40c and back surface side branch portion 40b extends in a straight line.

As described above, one end portion of through-hole 40 on the back surface side of photoelectric converter 10 branches off in multiple back surface side branch portions 40b. Each back surface side branch portion 40b opens on the back surface of photoelectric converter 10. In addition, the other end portion of through-hole 40 on the light-receiving surface side of photoelectric converter 10 branches off in multiple light-receiving surface side branch portions 40c. Each light-receiving surface side branch portion 40c opens on the light-receiving surface of photoelectric converter 10.

Through-hole electrode 20 is formed by filling a conductive material into through-hole 40.

Here, it is preferable that contact resistance between light-receiving surface side collecting electrode 15 and through-hole electrode 20 equal contact resistance between light-receiving surface side bus bar electrode 25 and through-hole electrode 20. Accordingly, the total of opening areas of four light-receiving surface side branch portions 40c on the light-receiving surface preferably is equal to the total of opening areas on the back surfaces of four back surface side branch portions 40b. For example, each of diameters of light-receiving surface side branch portions 40c is set to be 0.25 mm and each of back surface side branch portions 40b is set to be 0.25 mm.

In addition, it is preferable that inner resistance values of through-hole electrodes 20 be uniform. Accordingly, it is preferable that the cross-sectional area of through-hole electrode 20 be uniform from the end surface on the light-receiving surface side to the end surface on the back surface side.

In FIG. 11, through-hole electrode 20 and light-receiving surface side collecting electrode 15 are separated. However, they may be integrally formed in one process.

Although unillustrated, preferably, through-hole electrode 20 and photoelectric converter 10 are electrically insulated by applying an insulating process or by forming an insulating film on the inner wall of through-hole 40.

### Method for Manufacturing a Solar Cell

Next, a method for manufacturing solar cell 2 is described.

First, through-hole 40 is formed in photoelectric converter 10. Through-hole 40 can be formed by a laser method, etching method, sandblast method, or the like. For example, if the laser method is used, light-receiving surface side branch portion 40c and back surface side branch portion 40 b are formed sequentially by laser irradiation from the light-receiving surface side of photoelectric converter 10. Thereby, through-hole 40 shown in FIGS. 10 and 11 is formed. The method for forming through-hole 40 is not limited to this. Back surface side branch portion 40b may be formed by laser irradiation from the back surface side of photoelectric converter 10 and light-receiving surface side branch portion 40c may be formed by laser irradiation from the light-receiving surface side of photoelectric converter 10.

Next, photoelectric converter 10 is mounted on stage 50. In the embodiment, light-receiving surface side branch portion 40c and back surface side branch portion 40b have small diameters. Thus, any one of these can be placed with the surface facing down. Subsequently, an insulating film is formed in the inner wall of through-hole 40 by a well-known method.

Then, a conductive material is filled into through-hole 40 by a printing method, such as a screen printing method, off-set printing method, or ink-jet method. Thereby, through-hole electrode 20 is formed. As the conductive material, a silver paste in which silver particles are kneaded with an epoxy-based thermosetting resin or the like may be used. Preferably such conductive material has fluidity (low viscosity) to allow tight filling of through-hole 40.

Next, a conductive material with a predetermined pattern is provided on the light-receiving surface and back surface of photoelectric converter 10. Here, the predetermined pattern means shapes of light-receiving surface side collecting electrodes 15, light-receiving surface side bus bar electrodes 25, and back surface side collecting electrodes 30 shown in FIGS. 8 and 9. As the conductive material, similar to through-hole electrode 20, a silver paste in which silver particles are kneaded with an epoxy-based thermosetting resin or the like may be used. Thus, the present process may be carried out together with the process of filling the conductive material into through-hole 40.

Note that an insulating film should be formed in advance in portions, where light-receiving surface side bus bar electrodes 25 are formed, of the back surface of photoelectric converter 10.

### Advantageous Effects

Solar cell 2 according to the embodiment includes through-hole 40 passing through photoelectric converter 10 from the light-receiving surface to back surface of photoelectric converter 10. One end portion on the back surface side of through-hole 40 branches off in multiple back surface side branch portions 40b and back surface side branch portions 40b open on the back surface of photoelectric converter 10. In addition, the other end portion on the light-receiving surface side of through-hole 40 branches off in multiple light-receiving surface side branch portions 40c and light-receiving surface side branch portions 40c open on the light-receiving surface of photoelectric converter 10.

As described above, the opening areas of through-hole 40 on the light-receiving surface and back surface are small. Accordingly, even when a conductive material having fluidity is filled into through-hole 40, the conductive material can be prevented from flowing out from the opening of through-hole 40.

In addition, each of the end portions on the light-receiving surface side and back surface side of through-hole 40 branches off in multiple branch portions. Thus, in the process of pouring the conductive material in through-hole 40, photoelectric converter may be mounted with any one of the surfaces of the photoelectric converter facing down.

### Other Embodiments

The invention has been described by the above-described embodiments. However, it should not be understood that descriptions and drawings constituting one part of this disclosure limit the invention, and various alternative embodiments, examples, operational techniques would be clear for those who are in the art from this disclosure.

For example, in the first embodiment, through-hole 40 branches off only on the back surface, but through-hole 40 may branch off only on the light-receiving surface side. In this case, it is only needed that photoelectric converter 10 is mounted with the light-receiving surface facing down when the conductive material is filled into through-hole 40.

In addition, in the second embodiment, light-receiving surface side branch portion 40c is formed in place of light-receiving surface side trunk portion 40a, but both of light-receiving surface side trunk portion 40a and light-receiving surface side branch portion 40c may be provided.

Furthermore, in the first and second embodiments, the configurations in which solar cells 1 and 2 are provided with light-receiving surface side bus bar electrode 25 have been described. However, there is no need to provide light-receiving surface side bus bar electrode 25. In this case, wiring materials connecting multiple solar cells 1 or multiple solar cells 2 are needed only to be connected to through-hole electrodes 20.

As described above, the invention, of course, includes various embodiments which are not described herein. Thus, the technical scope of the invention is only limited by patent claims according to the scope of claims which is valid from the description above.

What is claimed is:

1. A solar cell comprising:
a photoelectric converter comprising a first surface and a second surface opposite to the first surface, the photoelectric converter configured to generate photo-generated carriers when the photoelectric converter receives light;
a hole passing through the photoelectric converter from the first surface to the second surface; and
an electrode comprising conductive material in the hole,
wherein a first end portion on the first surface side of the hole branches off in a plurality of first surface side branch portions and the first surface side branch portions open on the first surface.

2. The solar cell of claim 1, wherein a second end portion on the second surface side of the hole is connected to the plurality of first surface side branch portions and has one opening portion on the second surface.

3. The solar cell of claim 2, wherein the plurality of first surface side branch portions radially extend from the second surface side opening portion.

4. The solar cell of claim 2, wherein the plurality of first surface side branch portions extend from the second surface side opening portion with an inclination.

5. The solar cell of claim 1, wherein a diameter of an opening surface of the plurality of first surface side branch portions is at least 0.01 μm and no more than 2 mm.

6. The solar cell of claim 1, wherein the sum of vertical cross-sectional areas of the plurality of first surface side branch portions equals the vertical cross-sectional area of the second surface side opening portion.

7. The solar cell of claim 1, wherein the second end portion on the second surface side of the hole branches off in a plurality of second surface side branch portions and the second surface side branch portions open on the second surface.

8. The solar cell of claim 1, further comprising a plurality of collecting electrodes that are formed on at least one of the first and second surfaces and that collect the photo-generated carriers, wherein the electrode electrically connects to the plurality of collecting electrodes on the at least one surface.

9. The solar cell of claim 8, wherein the electrode is integrally formed with the plurality of collecting electrodes.
